(19) United States
(12) Patent Application Publication
(10) Pub. No.: US 2026/0173256 A1
(43) Pub. Date: Jun. 18, 2026

(54) WIRING CIRCUIT BOARD

(71) Applicant: NITTO DENKO CORPORATION, Osaka (JP)

(72) Inventors: Akane KOMORI, Osaka (JP); Hayato TAKAKURA, Osaka (JP); Izumi OZEKI, Osaka (JP)

(73) Assignee: NITTO DENKO CORPORATION, Osaka (JP)

(21) Appl. No.: 19/416,942

(22) Filed: Dec. 11, 2025

(30) Foreign Application Priority Data
Dec. 17, 2024 (JP) 2024-220878

(51) Int. Cl. H05K 1/02

(52) U.S. Cl. CPC H05K 1/0265; H05K 2201/09227; H05K 2201/09236; H05K 2201/09727

(57) ABSTRACT

A wiring circuit board includes a wire portion and a supporting portion capable of supporting one end of the wire portion. The wire portion includes a first insulating layer, a first wire, and a second wire. A width of the first wire is larger than a width of the second wire.

### CROSS REFERENCE TO RELATED APPLICATION

The present application claims priority to Japanese Patent Application No. 2024-220878, filed on Dec. 17, 2024, the contents of which are herein incorporated by reference in its entirety.

### TECHNICAL FIELD

The present invention relates to a wiring circuit board.

### BACKGROUND ART

Conventionally, there has been proposed a wiring circuit board including a plurality of wiring bodies disposed in parallel spaced relation to one another (ref: for example, Patent Document 1 below).

### CITATION LIST

### Patent Document

Patent Document 1: Japanese Unexamined Patent Publication No. 2019-212656

### SUMMARY OF THE INVENTION

### Problem to be Solved by the Invention

There is a demand for further improving the flexibility of circuit design in the wiring circuit board as described in Patent Document 1.

The present invention provides a wiring circuit board capable of achieving improvement of the flexibility of circuit design.

### Means for Solving the Problem

The present invention [1] includes a wiring circuit board, including a wire portion; and a supporting portion capable of supporting one end portion of the wire portion, the wire portion including an insulating layer; a first wire being disposed at one side of the insulating layer in a thickness direction of the insulating layer; and a second wire being disposed at one side of the insulating layer in the thickness direction and disposed so as to be spaced apart from the first wire in a width direction orthogonal to the thickness direction, a width of the first wire being larger than a width of the second wire.

According to this configuration, the wire portion has the first wire and the second wire. The width of the first wire is larger than the width of the second wire.

That is, two types of wires (first and second wires) having different widths can be disposed in one wire portion.

Accordingly, it is possible to achieve improvement of the flexibility of circuit design in the wiring circuit board including the wire portion and the supporting portion.

The present invention [2] includes the wiring circuit board described in [1], in which the wire portion further includes a metal supporting layer disposed at the other side of the insulating layer in the thickness direction, the first wire has, in the width direction, a first outer edge, and a first inner edge disposed between the first outer edge and the second wire, the second wire has, in the width direction, a second outer edge, and a second inner edge disposed between the second outer edge and the first wire, and when a center of a region between the first outer edge and the second outer edge in the width direction is determined as a first center, and a center of the metal supporting layer in the width direction is determined as a second center, the first center is disposed between the second center and the first outer edge in the width direction.

According to this configuration, the first center is shifted to the first outer edge side relative to the second center in the width direction.

Accordingly, even when the width of the metal supporting layer is limited, the second wire having a small width can be securely disposed at an inner side of the metal supporting layer.

As a result, the second wire can be securely supported by the metal supporting layer.

The present invention [3] includes the wiring circuit board described in the above-described [1] or [2], in which the wire portion further includes a metal supporting layer disposed at the other side of the insulating layer in the thickness direction, and entire of the first wire in the wire portion and entire of the second wire in the wire portion overlap with the metal supporting layer in the thickness direction.

According to this configuration, both the first wire and the second wire can be securely supported by the metal supporting layer.

The present invention [4] includes the wiring circuit board described in the above-described [2] or [3], in which the metal supporting layer has one side end portion and the other side end portion in the thickness direction, and a width of the metal supporting layer increases toward the one side end portion from the other side end portion.

According to this configuration, even when the width of the metal supporting layer is limited, the first wire and the second wire can be securely supported by the one side end portion of the metal supporting layer in the thickness direction.

The present invention [5] includes the wiring circuit board described in the above-described [2] or [3], in which the metal supporting layer has one side end portion and the other side end portion in the thickness direction, and a width of the one side end portion and a width of the other side end portion are larger than a width of the metal supporting layer between the one side end portion and the other side end portion.

According to this configuration, it is possible to increase the rigidity of the metal supporting layer in the thickness direction. Accordingly, the first wire and the second wire can be supported more securely.

The present invention [6] includes the wiring circuit board described in any one of the above-described [2] to [5], in which a width of the metal supporting layer is smaller than a width of the insulating layer.

### Effects of the Invention

According to the wiring circuit board of the present invention, it is possible to achieve improvement of the flexibility of circuit design.

### BRIEF DESCRIPTION OF THE DRAWINGS

FIG. 1 is a plan view of an embodiment of a wiring circuit board of the present invention.

FIG. 2 is a cross sectional view taken along line A-A of the wiring circuit board shown in FIG. 1.

FIG. 3 is a cross-sectional view showing a modification (1) of the wiring circuit board.

FIG. 4 is a cross-sectional view showing a modification (3) of the wiring circuit board.

### DESCRIPTION OF THE EMBODIMENTS

### 1. Wiring Circuit Board

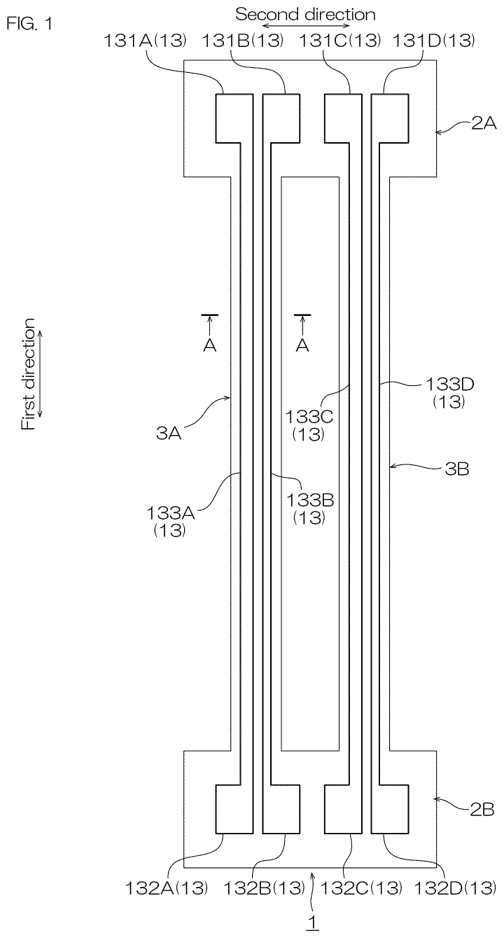

As shown in FIG. 1, the wiring circuit board 1 includes a plurality of supporting portions 2A, 2B and a plurality of wire portions 3A, 3B.

The supporting portions 2A and 2B are disposed so as to be spaced apart from each other in a first direction. Each of the supporting portions 2A and 2B extend in a second direction. The second direction is orthogonal to the first direction. The shapes of the supporting portions 2A and 2B are not limited. The supporting portion 2A supports one end portion of each of the wire portions 3A and 3B. Terminals 131A, 131B, 131C, and 131D of a circuit pattern 13 to be described later may be disposed on the supporting portion 2A. The supporting portion 2B supports the other end portion of each of the wire portions 3A and 3B. Terminals 132A, 132B, 132C, and 132D of the circuit pattern 13 to be described later may be disposed on the supporting portion 2B.

The wire portions 3A and 3B are disposed between the supporting portion 2A and the supporting portion 2B in the first direction. The wire portions 3A and 3B are aligned in the second direction. The wire portion 3B is disposed so as to be spaced apart from the wire portion 3A in the second direction. At least a portion of a wire 133A to be described later is disposed in the wire portion 3A. The wire portion 3A has a width in the width direction of the wire 133A and extends in a direction in which the wire 133A extends. In this embodiment, the direction in which the wire 133A extends is the same as the first direction, and the width direction of the wire 133A is the same as the second direction. The direction in which the wire 133A extends may be different from the first direction. The width direction of the wire 133A may be different from the second direction. At least a portion of a wire 133B to be described later is disposed in the wire portion 3B. The wire portion 3B has a width in the width direction of the wire 133B and extends in a direction in which the wire 133B extends. The wire portion 3B extends in the same direction as the wire portion 3A. One end portion of each of the wire portions 3A and 3B is connected to the supporting portion 2A. The other end portion of each of the wire portions 3A and 3B is connected to the supporting portion 2B. The shapes of the wire portions 3A and 3B are not limited. The wire portions 3A and 3B may be linear in shape or curved. Each of the wire portions 3A and 3B may be longer in length than the distance between the supporting portions 2A and 2B in the first direction.

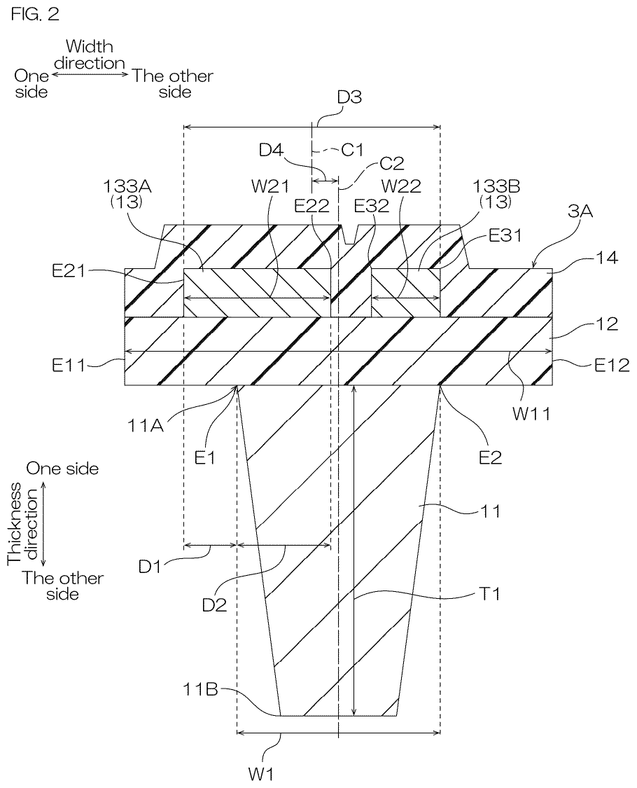

As shown in FIG. 2, the wire portion 3A includes a metal supporting layer 11, a first insulating layer 12, a circuit pattern 13, and a second insulating layer 14. In other words, the wiring circuit board 1 includes the metal supporting layer 11, the first insulating layer 12 (insulating layer), the circuit pattern 13, and the second insulating layer 14.

### (1) Metal Supporting Layer

The metal supporting layer 11 supports the first insulating layer 12, the circuit pattern 13, and the second insulating layer 14. The metal supporting layer 11 is made of metal. Examples of a material of the metal supporting layer 11 include copper, nickel, cobalt, iron, and alloys thereof. Examples of the alloy include stainless steel and copper alloy. As the material of the metal supporting layer 11, preferably, copper alloy is used.

The metal supporting layer 11 has one side end portion 11A and the other side end portion 11B in the thickness direction. In this embodiment, the width of the metal supporting layer 11 increases toward the one side end portion 11A from the other side end portion 11B. The width of the metal supporting layer 11 may be almost the same from the other side end portion 11B to the one side end portion 11A.

The metal supporting layer 11 of the wire portion 3A is disposed in a center portion of the wire portion 3A in the width direction. A width W1 of the one side end portion 11A of the metal supporting layer 11 of the wire portion 3A is smaller than a width W11 of the first insulating layer 12 of the wire portion 3A. The metal supporting layer 11 of the wire portion 3A is disposed between one side edge E11 of the first insulating layer 12 of the wire portion 3A and the other side edge E12 of the first insulating layer 12 of the wire portion 3A in the width direction. The metal supporting layer 11 of the wire portion 3A is disposed so as to be spaced apart from the one side edge E11 of the first insulating layer 12 of the wire portion 3A in the width direction. The metal supporting layer 11 of the wire portion 3A is disposed so as to be spaced apart from the other side edge E12 of the first insulating layer 12 of the wire portion 3A in the width direction.

The metal supporting layer 11 of the wire portion 3A has a thickness T1 of, for example, from 10 μm to 300 μm, preferably from 50 μm to 250 μm.

The one side end portion 11A of the metal supporting layer 11 of the wire portion 3A has a width W1 of, for example, from 5 μm to 300 μm, preferably from 10 μm to 250 μm.

A ratio (T1/W1) of the thickness T1 of the metal supporting layer 11 of the wire portion 3A to the width W1 of the one side end portion 11A of the metal supporting layer 11 of the wire portion 3A is, for example, 2 or more, preferably 5 or more. The ratio (T1/W1) is, for example, 30 or less, preferably 10 or less. The ratio (T1/W1) may be from 2 to 30 or from 5 to 10.

The metal supporting layer 11 may have a protective metal layer (first protective metal layer). The protective metal layer is disposed at one-side surface of the metal supporting layer 11 in the thickness direction. The protective metal layer protects the metal supporting layer 11. The protective metal layer is, for example, a sputtering layer. Examples of a material of the protective metal layer include chromium, copper, nickel, titanium, and alloys thereof.

### (2) First Insulating Layer

The first insulating layer 12 is disposed at one side of the metal supporting layer 11 in the thickness direction. In other words, the metal supporting layer 11 is disposed at the other side of the first insulating layer 12 in the thickness direction. The first insulating layer 12 is disposed on one-side surface of the metal supporting layer 11 in the thickness direction. The first insulating layer 12 is disposed between the metal supporting layer 11 and the circuit pattern 13 in the thickness direction. The first insulating layer 12 insulates the metal supporting layer 11 from the circuit pattern 13. The first insulating layer 12 is made of resin. Examples of the resin include polyimide, maleimide, epoxy resin, polybenzoxazole, and polyester.

### (3) Circuit Pattern

As shown in FIG. 1, the circuit pattern 13 includes the plurality of terminals 131A, 131B, 131C, and 131D, the plurality of terminals 132A, 132B, 132C, and 132D, and the plurality of wires 133A, 133B, 133C, and 133D. That is, the wiring circuit board 1 includes the wire 133A (first wire) and the wire 133B (second wire). The shape of the circuit pattern 13 is not limited.

The terminals 131A, 131B, 131C, and 131D are disposed on the supporting portion 2A. Each of the terminals 131A, 131B, 131C, and 131D has a square land shape.

The terminals 132A, 132B, 132C, and 132D are disposed on the supporting portion 2B. Each of the terminals 132A, 132B, 132C, and 132D has a square land shape.

The wire 133A electrically connects between the terminal 131A and the terminal 132A. One end portion of the wire 133A is connected to the terminal 131A. The other end portion of the wire 133A is connected to the terminal 132A.

The wire 133B electrically connects between the terminal 131B and the terminal 132B. One end portion of the wire 133B is connected to the terminal 131B. The other end portion of the wire 133B is connected to the terminal 132B.

At least a portion of the wire 133A and at least a portion of the wire 133B are disposed in the wire portion 3A. That is, the wire portion 3A has the wire 133A and the wire 133B. One end portion of the wire 133A and one end portion of the wire 133B may be disposed in the supporting portion 2A. The other end portion of the wire 133A and the other end portion of the wire 133B may be disposed in the supporting portion 2B.

The wire 133C electrically connects between the terminal 131C and the terminal 132C. One end portion of the wire 133C is connected to the terminal 131C. The other end portion of the wire 133C is connected to the terminal 132C.

The wire 133D electrically connects between the terminal 131D and the terminal 132D. One end portion of the wire 133D is connected to the terminal 131D. The other end portion of the wire 133D is connected to the terminal 132D.

At least a portion of the wire 133C and at least a portion of the wire 133D are disposed in the wire portion 3B. That is, the wire portion 3B has the wire 133C and the wire 133D. One end portion of the wire 133C and one end portion of the wire 133D may be disposed in the supporting portion 2A. The other end portion of the wire 133C and the other end portion of the wire 133D may be disposed in the supporting portion 2B.

As shown in FIG. 2, the circuit pattern 13 is disposed at one side of the first insulating layer 12 in the thickness direction. The circuit pattern 13 is disposed on one-side surface of the first insulating layer 12 in the thickness direction. The circuit pattern 13 is disposed on the opposite side of the metal supporting layer 11 with respect to the first insulating layer 12 in the thickness direction.

The circuit pattern 13 may have a protective metal layer (second protective metal layer). The protective metal layer is disposed on one-side surface of the first insulating layer 12 in the thickness direction. The protective metal layer protects the circuit pattern 13. The protective metal layer is, for example, a sputtering layer. Examples of a material of the protective metal layer include chromium, copper, nickel, titanium, and alloys thereof.

### (4) Second Insulating Layer

The second insulating layer 14 is disposed at one side of the first insulating layer 12 in the thickness direction. The second insulating layer 14 is disposed on one-side surface of the first insulating layer 12 in the thickness direction. The second insulating layer 14 covers all the wires 133A, 133B, 133C, and 133D. The second insulating layer 14 does not cover the terminals 131A, 131B, 131C, 131D, 132A, 132B, 132C, and 132D. The second insulating layer 14 is made of resin. Examples of the resin include polyimide, maleimide, epoxy resin, polybenzoxazole, and polyester.

### 2. Details of Wire Portion

Next, with reference to FIG. 2, details of the wire portion 3A will be described. The wire portion 3B has the same structure as the wire portion 3A. Therefore, the description of the wire portion 3B is omitted.

As described above, the wire portion 3A has the wire 133A and the wire 133B.

The wire 133A is disposed at one side of the first insulating layer 12 in the thickness direction of the first insulating layer 12. The wire 133A is disposed on one-side surface of the first insulating layer 12 in the thickness direction. The wire 133A is disposed on the opposite side of the metal supporting layer 11 with respect to the first insulating layer 12 in the thickness direction.

A width W21 of the wire 133A is larger than a width W22 of the wire 133B. The thickness of the wire 133A is the same as that of the wire 133B. Therefore, it is possible to send a larger current to the wire 133A than to the wire 133B. The wire 133A may be thicker than the wire 133B.

Specifically, the width W21 of the wire 133A is, for example, from 10 μm to 25 μm, preferably from 15 μm to 20 μm. The width W22 of the wire 133B is, for example, from 5 μm to 20 μm, preferably from 8 μm to 17 μm. The thickness of the wire 133A and the thickness of the wire 133B are, for example, from 1 μm to 20 μm, preferably from 5 μm to 15 μm.

The wire 133A has a first outer edge E21 and a first inner edge E22 in the width direction.

The first outer edge E21 is one side edge of the wire 133A in the width direction. The first outer edge E21 is disposed more to one side than the one side edge E1 of the metal supporting layer 11 in the width direction. In other words, the first outer edge E21 is disposed on the opposite side of the other side edge E2 of the metal supporting layer 11 relative to the one side edge E1 of the metal supporting layer 11 in the width direction. That is, the first outer edge E21 is disposed at an outer side of the metal supporting layer 11 in the width direction. The first outer edge E21 does not overlap with the metal supporting layer 11 in the thickness direction. Therefore, the width W21 of the wire 133A can be secured to the outside of the metal supporting layer 11.

A ratio (D1/W21) of a distance D1 in the width direction between the one side edge E1 of the metal supporting layer 11 and the first outer edge E21 to the width W21 of the wire 133A is, for example, 1/20or more, preferably 1/10 or more. When the ratio (D1/W21) is the above-described lower limit or more, the width W21 of the wire 133A can be further secured. The ratio (D1/W21) is, for example, less than ⅔, preferably ½ or less. When the ratio (D1/W21) is the above-described upper limit or less, the wire 133A can be securely supported by the metal supporting layer 11.

The first inner edge E22 is the other side edge of the wire 133A in the width direction. The first inner edge E22 is disposed between the first outer edge E21 and the wire 133B in the width direction. The first inner edge E22 is disposed more to the other side than the one side edge E1 of the metal supporting layer 11 in the width direction. In other words, the first inner edge E22 is disposed between the one side edge E1 of the metal supporting layer 11 and the other side edge E2 of the metal supporting layer 11 in the width direction. That is, the first inner edge E22 is disposed at an inner side of the metal supporting layer 11 in the width direction. The first inner edge E22 overlaps with the metal supporting layer 11 in the thickness direction. Therefore, the wire 133A can be supported by the metal supporting layer 11.

A ratio (D2/W21) of a distance D2 in the width direction between the one side edge E1 of the metal supporting layer 11 and the first inner edge E22 to the width W21 of the wire 133A is, for example, ⅓ or more, preferably more than ½. When the ratio (D2/W21) is the above-described lower limit or more, the wire 133A can be securely supported by the metal supporting layer 11. The ratio (D2/W21) is, for example, less than 1/1, preferably 19/20 or less, more preferably 9/10 or less. When the ratio (D2/W21) is the above-described upper limit or less, the width W21 of the wire 133A can be further secured.

The wire 133B is disposed at one side of the first insulating layer 12 in the thickness direction. The wire 133B is disposed on one-side surface of the first insulating layer 12 in the thickness direction. The wire 133B is disposed on the opposite side of the metal supporting layer 11 with respect to the first insulating layer 12 in the thickness direction. The wire 133B is disposed at the other side of the wire 133A in the width direction. The wire 133B is disposed so as to be spaced apart from the wire 133A in the width direction. Entire of the wire 133B is disposed between the one side edge E1 of the metal supporting layer 11 and the other side edge E2 of the metal supporting layer 11 in the width direction. That is, entire of the wire 133B is disposed at the inner side of the metal supporting layer 11 in the width direction. Entire of the wire 133B overlaps with the metal supporting layer 11 in the thickness direction.

The wire 133B has a second outer edge E31 and a second inner edge E32 in the width direction. The second outer edge E31 is the other side edge of the wire 133B in the width direction. The second outer edge E31 is disposed more to one side than the other side edge E2 of the metal supporting layer 11 in the width direction. The second outer edge E31 overlaps with the metal supporting layer 11 in the thickness direction. The second inner edge E32 is one side edge of the wire 133B in the width direction. The second inner edge E32 is disposed between the second outer edge E31 and the wire 133A in the width direction. The second inner edge E32 overlaps with the metal supporting layer 11 in the thickness direction. Therefore, the wire 133B can be supported by the metal supporting layer 11.

A ratio (D3/W1) of a distance D3 between the first outer edge E21 and the second outer edge E31 to the width W1 of the one side end portion 11A of the metal supporting layer 11 is, for example, 3.0 or less, preferably 2.0 or less. When the ratio (D3/W1) is the above-described upper limit or less, both the wires 133A and 133B can be securely supported by the metal supporting layer 11 while the width W21 of the wire 133A is secured. The ratio (D3/W1) is, for example, 1.0 or more, preferably 1.5 or more.

When the center of a region between the first outer edge E21 and the second outer edge E31 in the width direction is determined as a first center C1, and the center of the metal supporting layer 11 in the width direction is determined as a second center C2, the first center C1 is disposed between the second center C2 and the first outer edge E21 in the width direction. That is, the first center C1 does not coincide with the second center C2. The first center C1 is shifted to the first outer edge E21 side relative to the second center C2 in the width direction. This allows the wire 133B to be disposed at the inner side of the metal supporting layer 11.

A ratio (D4/D3) of a distance D4 between the first center C1 and the second center C2 to the distance D3 between the first outer edge E21 and the second outer edge E31 is, for example, ⅓ or less, preferably ¼ or less. When the ratio (D4/D3) is the above-described upper limit or less, it is possible to suppress excessive disposition of the first outer edge E21 at the outer side of the metal supporting layer 11. Thus, even when the width W21 of the wire 133A is larger than the width W22 of the wire 133B, both the wire 133A and the wire 133B can be securely supported by the metal supporting layer 11. The ratio (D4/D3) is, for example, 1/20 or more, preferably 1/10 or more.

A ratio (W22/W1) of the width W22 of the wire 133B to the width W1 of the one side end portion 11A of the metal supporting layer 11 is, for example, ⅔ or less, preferably ½ or less. When the ratio (W22/W1) is the above-described upper limit or less, the wire 133B is disposed at the inner side of the metal supporting layer 11, so that the wire 133B can be securely supported by the metal supporting layer 11. The ratio (W22/W1) is, for example, 1/10 or more, preferably ⅕ or more.

### 3. Operations and Effects

(1) According to the wiring circuit board 1, as shown in FIG. 2, the wire portion 3A has the wire 133A and the wire 133B. The width W21 of the wire 133A is larger than the width W22 of the wire 133B.

That is, two types of wires 133A, 133B having different widths can be disposed in one wire portion 3A.

Accordingly, it is possible to achieve improvement of the flexibility of circuit design in the wiring circuit board 1 including the wire portion 3A and the supporting portion 2A.

(2) According to the wiring circuit board 1, as shown in FIG. 2, the first center C1 is disposed between the second center C2 and the first outer edge E21 in the width direction. That is, the first center C1 is shifted to the first outer edge E21 side relative to the second center C2 in the width direction.

Accordingly, even when the width of the metal supporting layer 11 is limited, the wire 133B having a small width W22 can be securely disposed at an inner side of the metal supporting layer 11.

As a result, the wire 133B can be securely supported by the metal supporting layer 11.

(3) According to the wiring circuit board 1, as shown in FIG. 2, the width of the metal supporting layer 11 increases toward the one side end portion 11A from the other side end portion 11B.

Accordingly, even when the width of the metal supporting layer 11 is limited, the wire 133A and the wire 133B can be securely supported by the one side end portion 11A of the metal supporting layer 11 in the thickness direction.

### 4. Modification

Next, modifications will be described. In the modifications, the same reference numerals are provided for the same members as those in the embodiment, and the description thereof is omitted.

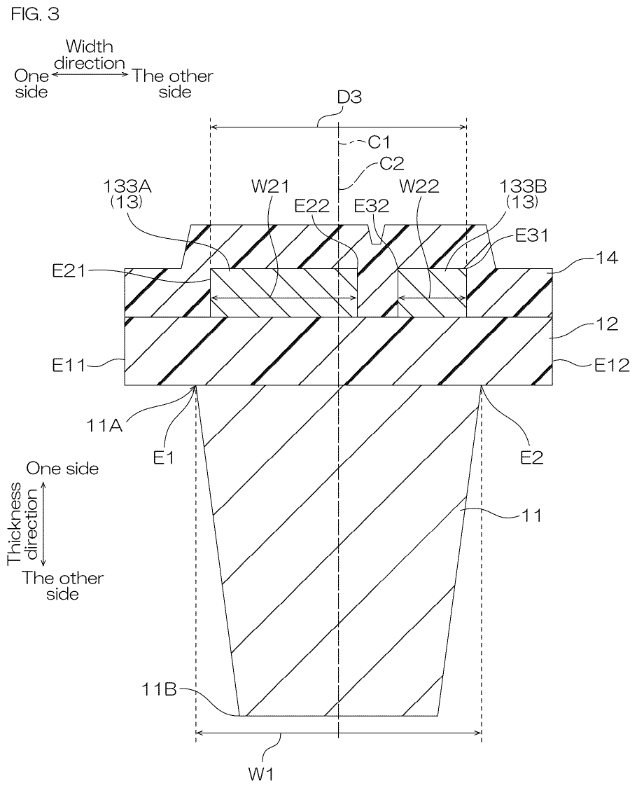

(1) As shown in FIG. 3, the width W1 of the one side end portion 11A of the metal supporting layer 11 in the thickness direction may be larger than the distance D3 between the first outer edge E21 and the second outer edge E31. In this case, the first outer edge E21 and the second outer edge E31 may overlap with the metal supporting layer 11 in the thickness direction. In other words, entire of the wire 133A in the wire portion 3A and entire of the wire 133B in the wire portion 3A overlap with the metal supporting layer 11 in the thickness direction. This allows both the wire 133A and the wire 133B to be securely supported by the metal supporting layer 11. The first center C1 may coincide with the second center C2.

(2) The first center C1 may be disposed between the second center C2 and the second outer edge E31 in the width direction. That is, the first center C1 may be shifted to the second outer edge E31 side relative to the second center C2 in the width direction.

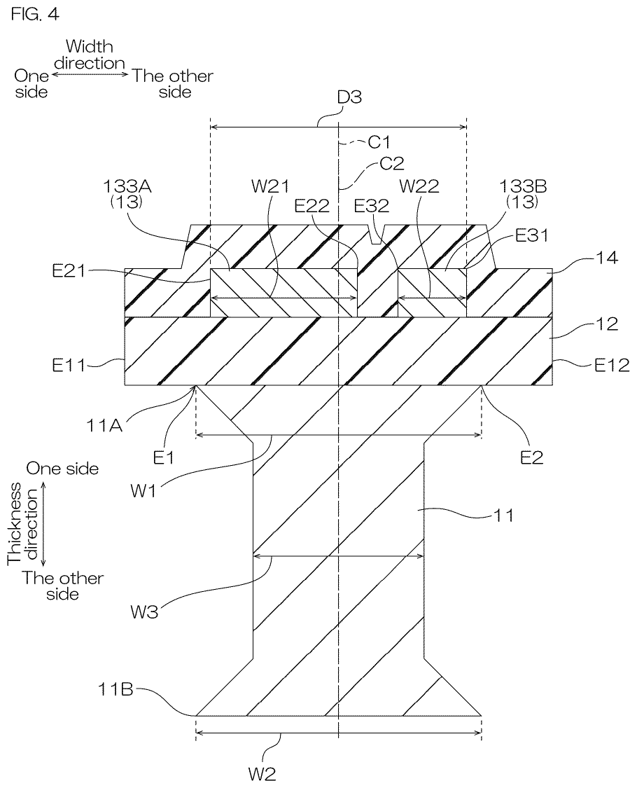

(3) As shown in FIG. 4, the cross-sectional shape of the metal supporting layer 11 may be a generally I-shape. Specifically, the width W1 of the one side end portion 11A of the metal supporting layer 11 and the width W2 of the other side end portion 11B of the metal supporting layer 11 are larger than the width W3 of the metal supporting layer 11 between the one side end portion 11A and the other side end portion 11B. The width W1 of the one side end portion 11A of the metal supporting layer 11 may be different from or the same as the width W2 of the other side end portion 11B of the metal supporting layer 11.

According to this modification, it is possible to increase the rigidity of the metal supporting layer 11 in the thickness direction. Accordingly, the wire 133A and the wire 133B can be supported more securely. This can suppress stress concentration on the wire 133A and the wire 133B when an external force is applied to the wire portion 3A. As a result, the occurrence of a crack in the wire 133A and the wire 133B can be suppressed.

(4) The modifications (1) to (3) can also achieve the same operations and effects as that of the above-described embodiment.

While the illustrative embodiments of the present invention are provided in the above description, such is for illustrative purpose only and it is not to be construed restrictively. Modification and variation of the present invention that will be obvious to those skilled in the art is to be covered by the following claims.

### INDUSTRIAL APPLICABILITY

The wiring circuit board of the present invention is available for use in connecting electronic elements.

### DESCRIPTION OF REFERENCE NUMERALS

1 wiring circuit board
2A supporting portion
3A wire portion
11 metal supporting layer
11A one side end portion of metal supporting layer in thickness direction
11B the other side end portion of metal supporting layer in thickness direction
12 first insulating layer (insulating layer)
133A wire (first wire)
E21 first outer edge
E22 first inner edge
W21 width of first wire
133B wire (second wire)
E31 second outer edge
E32 second inner edge
W22 width of second wire
C1 first center
C2 second center
W1 width of one side end portion of metal supporting layer in thickness direction
W2 width of the other side end portion of metal supporting layer in thickness direction
W3 width of metal supporting layer between one side end portion and the other side end portion

1.
A wiring circuit board, comprising:
a wire portion; and a supporting portion capable of supporting one end portion of the wire portion,
the wire portion comprising:
an insulating layer;
a first wire being disposed at one side of the insulating layer in a thickness direction of the insulating layer; and
a second wire being disposed at one side of the insulating layer in the thickness direction and disposed so as to be spaced apart from the first wire in a width direction orthogonal to the thickness direction,
a width of the first wire being larger than a width of the second wire.

2.
The wiring circuit board according to claim 1, wherein the wire portion further comprises a metal supporting layer disposed at the other side of the insulating layer in the thickness direction,
the first wire has, in the width direction, a first outer edge, and a first inner edge disposed between the first outer edge and the second wire,
the second wire has, in the width direction, a second outer edge, and a second inner edge disposed between the second outer edge and the first wire, and
when a center of a region between the first outer edge and the second outer edge in the width direction is determined as a first center, and a center of the metal supporting layer in the width direction is determined as a second center, the first center is disposed between the second center and the first outer edge in the width direction.

3. The wiring circuit board according to claim 2, wherein
the metal supporting layer has one side end portion and the other side end portion in the thickness direction, and
a width of the metal supporting layer increases toward the one side end portion from the other side end portion.

4. The wiring circuit board according to claim 2, wherein
the metal supporting layer has one side end portion and the other side end portion in the thickness direction, and
a width of the one side end portion and a width of the other side end portion are larger than a width of the metal supporting layer between the one side end portion and the other side end portion.

5. The wiring circuit board according to claim 2, wherein a width of the metal supporting layer is smaller than a width of the insulating layer.

6. The wiring circuit board according to claim 1, wherein
the wire portion further comprises a metal supporting layer disposed at the other side of the insulating layer in the thickness direction, and
entire of the first wire in the wire portion and entire of the second wire in the wire portion overlap with the metal supporting layer in the thickness direction.

7. The wiring circuit board according to claim 6, wherein
the metal supporting layer has one side end portion and the other side end portion in the thickness direction, and
a width of the metal supporting layer increases toward the one side end portion from the other side end portion.

8.
The wiring circuit board according to claim 6, wherein the metal supporting layer has one side end portion and the other side end portion in the thickness direction, and
a width of the one side end portion and a width of the other side end portion are larger than a width of the metal supporting layer between the one side end portion and the other side end portion.

9.
The wiring circuit board according to claim 6, wherein a width of the metal supporting layer is smaller than a width of the insulating layer.
